(19) United States
(12) Patent Application Publication
(10) Pub. No.: US 2016/0290788 A1
(43) Pub. Date: Oct. 6, 2016

(54) IN-PROCESS MONITORING OF COATINGS ON GLASS ARTICLES

(71) Applicant: PILKINGTON GROUP LIMITED, Lathom (GB)

(72) Inventors: KEVIN DAVID SANDERSON, UPHOLLAND (GB); ROBERT SCOTT WILSON, TOLEDO, OH (US)

(73) Assignee: PILKINGTON GROUP LIMITED, LATHOM (GB)

(21) Appl. No.: 14/392,396

(22) PCT Filed: Oct. 30, 2014
(86) PCT No.: PCT/GB2014/053229

§ 371 Date: Apr. 29, 2016

(30) Foreign Application Priority Data
Nov. 6, 2013 (GB) 1319559.9

(51) Int. Cl. G01B 11/06; C23C 16/52

(52) U.S. Cl. CPC G01B 11/0633; G01B 11/0691; G01B 11/0683; C23C 16/52

(57) ABSTRACT

Apparatus and method are described for monitoring of coatings deposited on glass articles during a continuous production process. Thus, coating quality is monitored without the need to interrupt the production process by removing an article to another site for analysis. The articles are illuminated and light reflected therefrom is analysed to provide an indication of layer thicknesses within the coating. Colour characteristics may also be reported.

The invention is concerned with in-situ monitoring during coating operations done on a variety of articles such as glass containers. The invention has utility in the field of glass vessel manufacture but is not limited thereto.

During manufacture of glass bottles, a coating of tin oxide is frequently applied to the bottle at the so-called ‘hot end’ of the process i.e. when recently cast bottle still retains a significant amount of heat. This coating serves a number of purposes.

For example, the coating reduces the degree of ‘scuffing’ (i.e. visible surface damage having an adverse aesthetic effect) during subsequent process steps. The coating also provides good adhesion for a subsequent polymer coating that is deposited at the ‘cold end’ of the process for additional lubrication. The coating also improves the strength of the bottle.

There is a need to monitor the quality of coatings applied to glass articles during production. Current systems employ Statistical Quality Control based approaches which involve measurements done ‘off-line’ i.e. on articles removed from the production line. A system which could monitor coating quality ‘on-line’, i.e. by performing measurements on articles without interrupting the continuous production process, would offer significant advantages over current systems.

In order to perform useful on-line monitoring, data acquisition and processing must be done rapidly enough to cope with the line speeds typically encountered during manufacture of bottles or other glass articles. In other words the system must be able to cope with the speed at which the article passes any sensor during data acquisition. This problem is more acute with bottles or other articles that present a round coated surface. For each article there is a very narrow window of opportunity during which data may be acquired as light is reflected back towards the sensor.

Prior art systems exist which provide estimates of (e.g.) coating thickness (or layer thicknesses with a coating stack) derived from spectral measurements done on coated glass articles. The term ‘coating stack’ is used in the art to refer to a coating comprising a series of thin layers of material which are typically deposited individually.

These systems typically rely on comparison of acquired spectral data (at one or two wavelengths) with a look-up table or mathematical model of a coated glass substrate. The calculations involved with mathematical models are cumbersome, particularly when employing a classical coated glass model where a series of matrix calculations are typically done. Even with more powerful modern day processors, this approach is less suitable for data acquisition and processing at the rates necessary for in-process monitoring of coatings that are applied during manufacture of, for example, coated glass bottles.

Also, these prior art systems use transmitted spectral data, which require location of the light source and detector on opposite sides of the article. They are impractical in the bottle manufacturing environment because proper alignment of the light source and detector is difficult and access to various components for maintenance is hindered.

U.S.2012/0182545 describes a system and method for determining optical characteristics, in particular haze, of transparent, scattering objects having transparent layers in an in-line coating system. The object is illuminated with a diffuse light source from where light in one direction on to the object is suppressed. By measuring transmitted light through the object in two directions, including the direction in which light is suppressed, data is acquired from which calculations of diffuse transmission and total transmission may be performed.

U.S.2005/0167264 A1 describes methods and apparatus for measuring selected optical characteristics of coatings formed on substrates during the deposition process. A retro-reflector is employed to reflect transmitted light back through the coated substrate and selected properties of the beam so reflected are measured. The system is designed for use under vacuum.

U.S. Pat. No. 5,396,080 describes a system for monitoring the thickness and quality of coatings applied to a sheet substrate. A polychromatic light source is directed at the coating and the intensity of reflected light of at least two discrete monitoring wavelengths is measured. Said measurements are processed to generate an electrical signal which can be compared with threshold values to determine whether predetermined tolerance values have been exceeded.

The system uses spatially separated light source and detector and data is acquired from a plurality of locations on the substrate, which features render the system unsuitable for on-line monitoring of glass vessels during production.

According to the present invention, apparatus for monitoring coatings comprising one or more layers, applied to articles during a continuous production process comprises the features set out in claim 1 attached hereto.

In a preferred embodiment the processing means is arranged to cause the spectrometer to perform at least one measurement in every 250 ms.

In a further preferred embodiment, the processing means is arranged to perform each measurement over a duration of between 50 ms and 200 ms.

In a further embodiment, the processing means is arranged to determine whether light reflected from the location during a given measurement exceeds a preselected intensity threshold and to reject data obtained from the given measurement if it does not. More preferably, the processing means is arranged to add data obtained from measurements done immediately before and immediately after the given measurement when the light reflected during the given measurement exceeds the preselected intensity threshold.

A further preferred embodiment is arranged for monitoring coatings applied to articles passing through the location at a rate of at least four articles per second, preferably eight articles per second.

The processor may be further arranged to provide an indication of colour value from the acquired data.

Apparatus according to the invention is especially suited to on-line monitoring of coatings deposited on bottles, jars or other glass articles, particularly by chemical vapour deposition (CVD) during a continuous production process.

Throughout this specification, reference is made to ‘light’ for convenience but this should not be as limiting to any part of the electromagnetic spectrum. The term ‘light’ is intended to embrace electromagnetic radiation of any wavelength suitable for operation of the invention and includes, but is not limited to, such radiation have a wavelength in the range 400-700 nm.

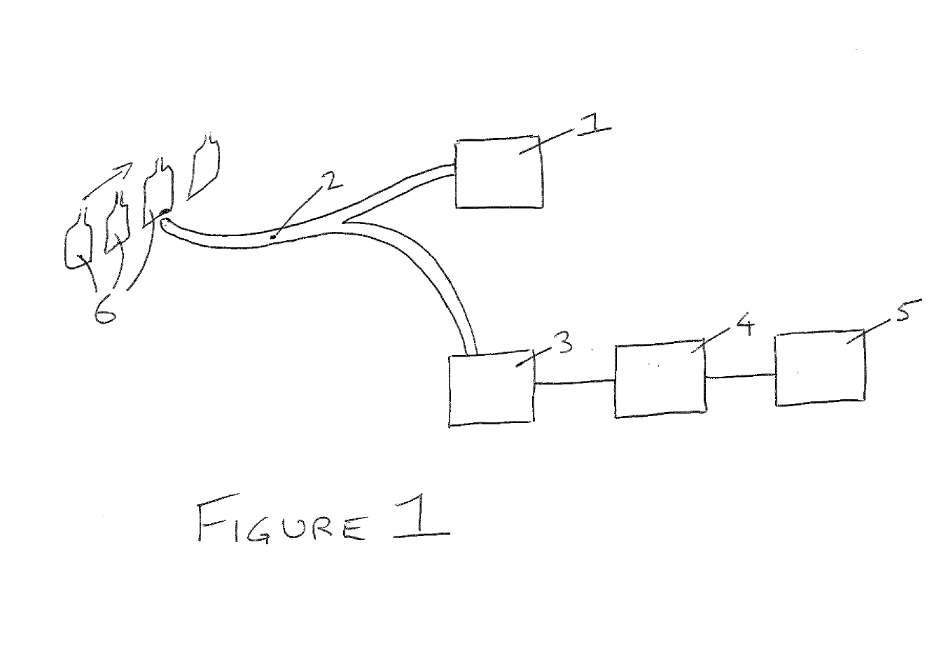

The invention will now be described with reference to FIG. 1, which is a schematic representation of apparatus according to the invention.

Referring to FIG. 1, apparatus according to the invention includes a source 1 of light, a fibre optic network 2, a spectrometer 3, a processor 4 and a man-machine interface 5 such as a screen/keyboard combination. Fibre optic network 2 comprises a plurality of individual fibre optic cores (not shown) in an arrangement that is well known. An optical arrangement (e.g. one or more lenses, not shown) may also be included to improve concentration of light on to the articles and gathering of reflected light at the end of the fibre optic network for transmission back to the spectrometer.

During operation, light from light source 1 is directed along some of the cores in network 2 to illuminate coated articles 6 (for example, glass vessels). During the transit of each article 6, a brief window of opportunity exists during which the article is aligned such that light reflected therefrom is directed along other cores in network 2 for detection by spectrometer 3. Thus, the apparatus provides for analysis of light that is reflected from light that is reflected from the surface of the article, rather that light that is transmitted therethrough. This allows for an arrangement where illumination and light collection are done on the same side of the article. Such an arrangement better suits the environment of a continuous production process where available space is limited and occupied by other equipment.

Spectrometer 3 provides to processor 4, electronic data representative of the spectrum of light reflected by article 6. Processor 4 uses said electronic data to calculate coating thicknesses and other parameters as will be further explained below.

Spectrometer 3 is arranged to report measurements of reflected radiation (typically) every 50 milliseconds (ms).

Processor 4 is arranged to analyze (typically) each 50 ms measurement as it received from the spectrometer 3. The signal undergoes a preliminary analysis and if the signal strength does not meet a pre-determined criterion, the measurement will be ignored as being a measurement that occurred when there was no bottle present in the location illuminated by the light source/fibre optic network. If the signal strength meets the pre-determined criterion, it will indicate that a bottle was present in the location and the measurement will be used further by processor 4. In order to ensure that all reflected light is captured from a given bottle, the processor may be arranged to add the measurements derived from the 50 ms intervals immediately before and after an interval where a bottle is deemed present, to the measurement for that interval. Such an arrangement is especially suited to analysis of coatings on articles presenting a round surface.

By one approach, processor 4 averages together the spectral data of a pre-set number of “good” measurements (bottles) together and then performs the thickness analysis.

By an alternative approach, the processor performs a moving average of the spectral data by calculating the average of the spectral data of the last pre-set number of “good” measurements (bottles) collected and is calculated after each “good” measurement is detected. The processor performs the thickness analysis with each moving average result.

The averaged spectrum is then used to calculate film thicknesses for the coating (as well as a measured colour value). A series of reflectance values at wavelengths increasing by 5 nm from 400 nm to 700 nm (i.e. 61 values in total) are passed to a multi-variable fitting routine which compares the measured values against a theoretical thin-film stack model and regressively determines the desired film stack properties that best matches the measured reflection values.

Previous measurements done on an uncoated substrate (bottle) provide reference data.

The mathematical techniques used for these calculations are generally known to a person skilled in the art but a number of features are included which allow for the rapid data acquisition necessary to use the invention for monitoring of glass vessels during a continuous production process.

First, as previously noted, the calculation involves a number of multiplications involving 2×2 matrices. Two of the terms in each of these matrices are either 0 or 1 and it is computationally inefficient to perform all of the multiplications by these terms. Instead, the result of all matrix calculations is represented as a single equation which allows for elimination of all of the steps involving multiplication by 0 or 1. This results in a calculation procedure with fewer mathematical operations than would occur otherwise.

Appendix 1 provides a further explanation of this approach.

Second, thin film modelling typically assumes an abrupt, well defined interface between layers and reflection of light at such an interface is dependent on the refractive indices of the materials in each layer. However, in practice these interfaces are not abrupt and well defined, rather the layers have a degree of roughness.

This roughness of the layers gives rise to a region where intermingling of the two adjacent materials occurs which has the observed effect of decreasing the amount of light that is reflected from an interface.

Prior art approaches to this problem typically regard this region of intermingling as a layer in its own right and a refractive index is assigned that represents a mixture of the materials on either side. This assumed additional layer is known as an “effective medium”.

By this prior art approach, a single layer applied to a glass substrate would be represented in the mathematical model as the applied layer plus a layer having a refractive index that is intermediate between that of the applied layer and the air above it. A three layer stack would be represented as six layers etc. So, it can be seen that this approach to modelling of the stack gives rise to cumbersome calculations.

The inventors use a model that describes a smooth transition of optical properties throughout the region of intermingling between layers in a stack.

By this approach, the optical properties of a (for example) three layer film stack may be calculated as such whereas, by prior art approaches, such a stack would have to be treated as a six layer coating.

Appendix 2 provides further details of this approach.

These techniques of reducing a plurality of matrices to a single equation and obviating the need to represent the intermediate region between layers as a further layer allow for faster data processing using reflectance values at a much greater number of wavelengths (e.g. 61 values) than previously seen. In other words, the invention includes processing means that are uniquely programmed to allow for real-time accurate monitoring of coated articles during the production process, at a rate that was hitherto not achievable.

### Appendix 1—Pre-calculation of Film Model 2×2 Matrices

Generally, a 2×2 matrix calculation is given by:

$$[ \begin{matrix}{I}_{11} & {I}_{12} \\ {I}_{21} & {I}_{22}\end{matrix} ] \times [ \begin{matrix}{L}_{11} & {L}_{12} \\ {L}_{21} & {L}_{22}\end{matrix} ] = [ \begin{matrix}{I}_{11} \cdot {L}_{11} + {I}_{12} \cdot {L}_{21} & {I}_{11} \cdot {L}_{12} + {I}_{12} \cdot {L}_{22} \\ {I}_{21} \cdot {L}_{11} + {I}_{22} \cdot {L}_{21} & {I}_{21} \cdot {L}_{12} + {I}_{22} \cdot {L}_{22}\end{matrix} ]$$

· represents a scalar multiplication

So a single 2×2 matrix calculation gives rise to 8 multiplication operations and 4 addition operations.

Thin film modelling represents the interface between two materials (a and b) using “Interface” (I_{ab}) and “Layer” (L_{b}) matrices:

$$\begin{matrix}\begin{matrix}{I}_{ab} = [ \begin{matrix}\frac{1}{{t}_{ab}} & \frac{{r}_{ab}}{{t}_{ab}} \\ \frac{{r}_{ab}}{{t}_{ab}} & \frac{1}{{t}_{ab}}\end{matrix} ] \\ = ( \frac{1}{{t}_{ab}} ) [ \begin{matrix}1 & {r}_{ab} \\ {r}_{ab} & 1\end{matrix} ]\end{matrix} & Equation 1 \\ {L}_{b} = [ \begin{matrix}{e}^{j β} & 0 \\ 0 & {e}^{- j β}\end{matrix} ] & Equation 2\end{matrix}$$

which are multiplied together during calculation of the thickness of b:

$${I}_{ab} \times {L}_{ab} = \frac{{e}_{b}}{{t}_{ab}} [ \begin{matrix}1 & {r}_{ab} \\ {r}_{ab} & 1\end{matrix} ] \times [ \begin{matrix}1 & 0 \\ 0 & {e}_{b}^{- 2}\end{matrix} ] \qquad Equation 3$$

where:

$${r}_{ab} = \frac{{N}_{a} cos {φ}_{a} - {N}_{b} cos {φ}_{b}}{{N}_{a} cos {φ}_{a} + {N}_{b} cos {φ}_{b}} ( for s \text{-} polarization )$$

$$and$$

$${r}_{ab} = \frac{{N}_{b} cos {φ}_{a} - {N}_{a} cos {φ}_{b}}{{N}_{b} cos {φ}_{a} + {N}_{a} cos {φ}_{b}} ( for p \text{-} polarization )$$

$${e}_{b} = {e}^{jβ}$$

where:

$$β = \frac{2 π {d}_{b} {N}_{b}}{λ} cos {φ}_{b}$$

Nₐ=refractive index of material a;

N_{b}=refractive index of material b;

Φₐ=angle of incidence;

Φ_{b}=angle of refraction;

d_{b}=thickness of material b;

λ=wavelength

N.B. Calculations are performed for two polarisation states (s and p), the results of which are combined for the final reflection calculation.

Expanding the matrix product of equation 3 gives:

$$\begin{matrix}{I}_{ab} \times {L}_{b} = \frac{{e}_{β}}{{t}_{ab}} [ \begin{matrix}1 & {r}_{ab} \\ {r}_{ab} & 1\end{matrix} ] \times [ \begin{matrix}1 & 0 \\ 0 & {e}_{β}^{- 2}\end{matrix} ] \\ = \frac{{e}_{β}}{{t}_{ab}} [ \begin{matrix}1 \cdot 1 + 0 \cdot {r}_{ab} & 1 \cdot 0 + {r}_{ab} \cdot {e}_{β}^{- 2} \\ 1 \cdot {r}_{ab} + 0 \cdot 1 & {r}_{ab \cdot } 0 + 1 \cdot {e}_{β}^{- 2}\end{matrix} ] \\ = \frac{{e}_{b}}{{t}_{ab}} [ \begin{matrix}1 & {r}_{ab} {e}_{β}^{- 2} \\ {r}_{ab} & {e}_{β}^{- 2}\end{matrix} ]\end{matrix}$$

Thus it can be seen that the operation of multiplying the interface and layer matrices reduces to a simple multiplication operation.

Reference: “Ellipsometry and Polarized Light” R. M. A. Azzam and N. M. Bashara, 1977, 1987.

### Appendix 2—Treatment of Interface Region between Rough Layers

The classic thin film modelling approach to a single, rough layer on a substrate is to treat the region of intermixing as an additional (“equivalent”) layer (see ref 1). The scattering matrix representing a system comprising two films (1 and 2) between an effectively infinite ambient (0) and a substrate (3) is given by:

$$\begin{matrix}S = {I}_{01} {L}_{1} {I}_{12} {L}_{2} {I}_{23} \\ = ( \frac{1}{{t}_{01} {t}_{12} {t}_{23}} ) [ \begin{matrix}1 & {r}_{01} \\ {r}_{01} & 1\end{matrix} ] [ \begin{matrix}{e}^{j {β}_{1}} & 0 \\ 0 & {e}^{- {jβ}_{1}}\end{matrix} ] \\ = [ \begin{matrix}1 & {r}_{12} \\ {r}_{12} & 1\end{matrix} ] [ \begin{matrix}{e}^{j {β}_{2}} & 0 \\ 0 & {e}^{- j {β}_{2}}\end{matrix} ] [ \begin{matrix}1 & {r}_{23} \\ {r}_{23} & 1\end{matrix} ]\end{matrix} \qquad Equation 4$$

In the classic approach to thin film modelling of a rough layer, layer number 1 in equation 1 would be the equivalent layer.

The corresponding equation for a single film (1) sandwiched between ambient (0) and substrate (2) is:

$$\begin{matrix}S = {I}_{01} {L}_{1} {I}_{12} \\ = ( \frac{1}{{t}_{01} {t}_{12}} ) [ \begin{matrix}1 & {r}_{01} \\ {r}_{01} & 1\end{matrix} ] [ \begin{matrix}{e}^{j β} & 0 \\ 0 & {e}^{- j β}\end{matrix} ] [ \begin{matrix}1 & {r}_{12} \\ {r}_{12} & 1\end{matrix} ]\end{matrix} \qquad Equation 5$$

From a comparison of equations 4 and 5 it can be seen clearly that the mathematical operations involved for an analysis of a two layer system (between air and substrate) are far more complex than for a single layer.

The relative complexities of the two systems are further illustrated as the matrix multiplications are done to provide equations for reflection and scattering at the various interfaces. For brevity, these operations are not reproduced here but for a fuller analysis, see Ref 1.

By the approach of the current inventors, the equivalent layer is dispensed with and a two-layer system having a rough interface is treated as two media having a smooth transition therebetween (so called Epstein Layers, see ref 2). The first three multiplying matrices, I₀₁×L₁×L₁₂, of equation 1 reduce to a single interface matrix having terms adjusted to take account of the Epstein layer:

$${I}_{01} \times {L}_{1} \times {I}_{02} \to {I}_{02} = \frac{1}{{t}_{02}} [ \begin{matrix}1 & {r}_{02}^{*} \\ {r}_{02}^{*} & 1\end{matrix} ]$$

where:

$${r}_{02}^{*} = \frac{sin {h}^{2} ( \frac{{π}^{2} d}{2 λ} ( {n}_{2} cos {φ}_{r} - {n}_{0} cos {φ}_{i} ) )}{sin {h}^{2} ( \frac{{π}^{2} d}{2 λ} ( {n}_{2} cos {φ}_{r} + {n}_{0} cos {φ}_{i} ) )} for s \text{-} polarization and$$

and:

$${r}_{02}^{*} = \frac{sin {h}^{2} ( \frac{{π}^{2} d}{2 λ} ( {n}_{2} cos {φ}_{i} - {n}_{0} cos {φ}_{r} ) )}{sin {h}^{2} ( \frac{{π}^{2} d}{2 λ} ( {n}_{2} cos {φ}_{i} + {n}_{0} cos {φ}_{r} ) )} for p \text{-} polarization ,$$

d=thickness of the intermixed “roughness” layer;

λ=wavelength of incident radiation;

Φᵢ=angle of incidence;

Φᵣ=angle of reflection;

n₀=refractive index of material 0 and

n₂=refractive index of material 2.

Thus, the representation of a coating stack having rough interfaces between adjacent layers is greatly simplified, in comparison with previous attempts to model theses systems for monitoring apparatus. The mathematical operations are correspondingly simpler which provides for faster data processing, suited to on-line monitoring of continuous systems.

Ref 1. “Ellipsometry and Polarized Light” R. M. A. Azzam and N. M. Bashara, 1977, 1987.

Ref 2. “Optics of Thin Films” Knittl, 1976

Ref 3. See also P. Epstein, Proc Natl. Acad. Sci. USA 16 (1930).

1.-10. (canceled)

11. A method for monitoring a coating comprising one or more layers applied to a round surface of each of a plurality of articles during and without interrupting a continuous production process for said articles, comprising:
providing a source of electromagnetic radiation, a spectrometer, and a fibre optic network, the fiber optic network being arranged to direct radiation from the source of electromagnetic radiation to a location through which the articles pass during the production process, and to direct radiation reflected from said location to the spectrometer;
utilizing a processing means to cause the spectrometer to perform a series of measurements of radiation at a plurality of wavelengths reflected from said location;
determining the thickness of the one or more layers based on said measurements; and
providing an indication of said thickness to a man-machine interface.

12. The method of claim 11, wherein said articles pass through said location at a rate of at least four articles per second.

13. The method of claim 11, wherein the processing means causes the spectrometer to perform at least one measurement every 250 ms.

14. The method of claim 11, wherein the processing means causes the spectrometer to perform a measurement every 50 ms to 200 ms.

15. The method of claim 11, wherein the processing means determines whether light reflected from said location for a given measurement exceeds a preselected intensity threshold and rejects data obtained from the given measurement if it does not.

16. The method of claim 15, wherein the processing means utilizes data obtained from measurements done immediately before and immediately after the given measurement when the light reflected during the given measurement exceeds the preselected intensity threshold.

17. The method of claim 11, wherein said articles pass through said location at a rate of at least eight articles per second.

18. The method of claim 11, further comprising determining a color value based on said measurements and providing an indication of said color value to the man-machine interface.

19. The method of claim 11, further comprising deposition the one or more layers to each of the articles by chemical vapor deposition.

20. The method of claim 11, wherein each of the articles comprises a glass bottle or jar.

21. An apparatus for monitoring coatings comprising one or more layers, applied to articles during a continuous production process comprising:
a source of electromagnetic radiation;
a spectrometer;
a fibre optic network arranged to direct radiation from the source to a location through which the articles pass during the production process and further arranged to direct radiation reflected from said location to the spectrometer;
a man-machine interface; and
processing means
the processing means being arranged to cause the spectrometer to perform a series of measurements of radiation at a plurality of wavelengths, reflected from the location through which the articles pass; to perform a calculation of thicknesses of the layers based on the measured radiation and to provide an indication of said thicknesses to the man-machine interface.

22. The apparatus according to claim 21, wherein the processing means is arranged to cause the spectrometer to perform at least one measurement in every 250 ms.

23. The apparatus according to claim 21, wherein the processing means is arranged to perform each measurement over a duration of between 50 ms and 200 ms.

24. The apparatus according to claim 21, wherein the processing means is arranged to determine whether light reflected from the location during a given measurement exceeds a preselected intensity threshold and to reject data obtained from the given measurement if it does not.

25. The apparatus according to claim 24, wherein the processing means is arranged to add data obtained from measurements done immediately before and immediately after the given measurement when the light reflected during the given measurement exceeds the preselected intensity threshold.

26. The apparatus according to claim 21, for monitoring coatings applied to articles passing through the location at a rate of at least four articles per second.

27. The apparatus according to claim 26, for monitoring coatings applied to articles passing through the location at a rate of at least eight articles per second.

28. The apparatus according to claim 21, wherein the processor is further arranged to provide an indication of colour value to the man-machine interface.
